(19) United States
(12) Patent Application Publication
(10) Pub. No.: US 2023/0318165 A1
(43) Pub. Date: Oct. 5, 2023

(54) ELECTRONIC DEVICE

(71) Applicant: STMicroelectronics (Grenoble 2) SAS, Grenoble (FR)

(72) Inventors: Romain COFFY, Voiron (FR); Ouafa HAJJI, Voiron (FR); Asma HAJJI, Voiron (FR); Fabien QUERCIA, Saint Marcelin (FR)

(73) Assignee: STMicroelectronics (Grenoble 2) SAS, Grenoble (FR)

(21) Appl. No.: 18/119,026

(22) Filed: Mar. 8, 2023

(30) Foreign Application Priority Data
Mar. 14, 2022 (FR) 2202214

(51) Int. Cl. H01Q 1/22; H01L 23/58; H01L 23/544; H01L 21/56; H01Q 1/48

(52) U.S. Cl. CPC H01Q 1/2283; H01L 21/56; H01L 23/544; H01L 23/585; H01Q 1/48; H01L 24/16; H01L 2223/54426

(57) ABSTRACT

An electronic device includes an electronic integrated circuit chip assembled on a first region of a substrate. A radiation element of an antenna is mounted to the substrate in a manner where it is separated from the substrate by a second layer of a second dielectric material, and i\s further offset with respect to the first region of the substrate so that the radiation element does not cover the electronic integrated circuit chip. A first coating layer of a first coating material covers at least a surface of the electronic integrated circuit chip facing away from the substrate further covers a surface of the radiation element facing away from the substrate.

### PRIORITY CLAIM

This application claims the priority benefit of French Application for Patent No. 2202214, filed on Mar. 14, 2022, the content of which is hereby incorporated by reference in its entirety to the maximum extent allowable by law.

### TECHNICAL FIELD

The present disclosure generally relates to electronic devices and their manufacturing methods, particularly wireless communication electronic devices.

### BACKGROUND

Electronic devices, particularly electronic devices for wireless communication at high frequency, for example higher than 50 GHz, may use patch-type antennas. A patch antenna is a planar antenna having a radiating element separated from a conductive reflective plane by a dielectric blade having its thickness depending on the wavelength of the desired communication signal.

Electronic devices with planar antennas may comprise an electronic chip configured to transmit and/or to receive signals via the planar antenna. However, existing solutions for integrating an electronic chip with a patch antenna are expensive to manufacture. Further, the performances of current solutions are not optimal since the accuracies to be respected for the placing and the shaping of the patch antenna are in the order of a few tens of micrometers.

There is a need to improve current electronic devices as well as their manufacturing methods. There further is a need to decrease the thickness of electronic devices to allow their optimal integration.

There is a need to overcome all or part of the disadvantages of known electronic devices.

### SUMMARY

An embodiment provides an electronic device comprising: an electronic chip mounted on a first region of a substrate of the electronic device; a first coating layer of a first coating material covering at least a surface of the electronic chip facing away from the substrate; and a radiation element of an antenna of the electronic device, separated from the substrate by a second layer of a second dielectric material, and being offset with respect to the first region of the substrate so that the radiation element does not cover the electronic chip; a surface of the radiation element facing away from the substrate being covered with the first coating layer.

An embodiment provides a method of manufacturing an electronic device comprising: providing an electronic chip, the electronic chip being assembled on a first region of a substrate of the electronic device; forming a radiation element so that it is separated from the substrate by a second layer made of a second dielectric material and offset with respect to the first region of the substrate to avoid covering the electronic chip; and forming a first coating layer of a first coating material to cover at least a surface of the radiation element and at least a surface of the electronic chip facing away from the substrate.

In an embodiment, the electronic chip is configured for exciting the radiation element with a communication signal.

In an embodiment, the substrate comprises: a ground layer supporting at least a conductive surface, coupled to ground, and provided with an opening; and a signal layer provided with at least one signal line and arranged in front of at least a portion of the opening of the ground layer; the radiation element being arranged in front of at least a portion of the opening of the ground layer, the ground layer being arranged between the signal layer and the radiation element.

In an embodiment, the bonding element is arranged between the second layer and the substrate to bond at least the second layer to the substrate.

In an embodiment, the bonding element has a thickness in the range from 5 to 15 micrometers.

In an embodiment, the second layer has a thickness in the range from 260 to 290 micrometers.

In an embodiment, the radiation element rests on the second layer and has a lateral extension which is smaller than a lateral extension of the second layer.

In an embodiment, one or a plurality of alignment elements are arranged at the level of the substrate to guide the positioning of at least the second layer.

In an embodiment, the forming of the radiation element comprises: a step of forming of a layer of the second dielectric material, intended to form the second layer of the second material, followed by a step of thickness decrease of said layer; a step of creation of a conductive layer so that it rests on a surface of said layer of the second material, having had its thickness decreased at the thickness decrease step and so that said conductive layer is divided into one or a plurality of conductive elements, each having a lateral dimension similar to that of the radiation element; and a singulation step during which is cut, from the assembly obtained after the creation step, one or a plurality of blocks of radiation elements comprising at least one of said conductive elements and a portion of the layer of the second material corresponding to the second layer of the second material having said conductive element resting thereon.

In an embodiment, the forming of the radiation element comprises a placement step during which at last one of said blocks of radiation elements is positioned in contact with the substrate so that the radiation element is offset with respect to the first region of the substrate and does not cover the electronic chip.

In an embodiment, the placement step comprises an alignment step using said one or a plurality of alignment elements to position at least one of said blocks of radiation elements.

In an embodiment, at the end of the thickness decrease step, a thickness of the second layer of the second material is in the range from 260 micrometers to 300 micrometers.

In an embodiment, the forming of the first coating layer comprises a thickness decrease step during which the thickness of coating material is decreased so that the first layer of coating material covers the radiation element with a thickness in the range from 30 micrometers to 150 micrometers.

In an embodiment: during the step of forming of the layer of second material, said layer of the second material is formed on a bonding portion intended to form the bonding element after the singulation step; and during the singulation step, the bonding portion is cut so that said one or a plurality of blocks of radiation elements each comprise the bonding element.

In an embodiment, the placement step comprises a thermal and/or compression treatment applied to said one or a plurality of blocks of radiation elements after positioning.

An embodiment provides an electronic system comprising such a first electronic device, and such a second electronic device, the two electronic devices being configured to exchange a communication signal via their respective radiation element.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 is a cross-section view showing an electronic device according to an embodiment of the present disclosure;

FIG. 2 is a top view showing an electronic device according to another embodiment of the present disclosure;

FIG. 3 shows a method of manufacturing the electronic device of FIG. 1 according to an embodiment of the present disclosure;

FIG. 4 shows the method of FIG. 3 in the form of blocks; and

FIG. 5 shows an electronic system according to an embodiment of the present disclosure.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., it is referred to the orientation of the drawings or to an electronic device in a normal position of use.

Unless specified otherwise, the expressions “around”, “approximately”, “substantially” and “in the order of” signify within 10%, and preferably within 5%.

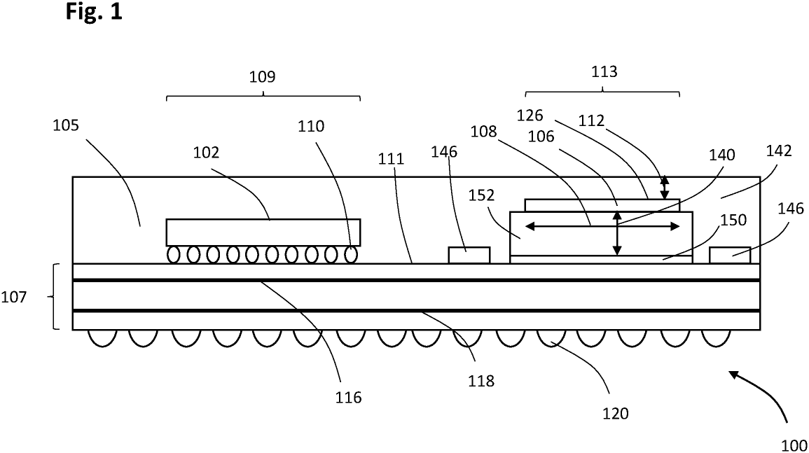

FIG. 1 schematically shows a cross-section view of an electronic device 100 according to an embodiment of the present disclosure.

The electronic device of FIG. 1 comprises an electronic integrated circuit chip 102 configured to excite a radiation element 106 of an antenna of the electronic device with a communication signal. The excitation of the radiation element is, for example, configured to generate a radio frequency communication signal from radiation element 106.

Electronic chip 102 comprises, for example, contact pads 110, for example in the form of balls. The contact pads are, in another example, flat. The contact pads are, for example, all arranged on a same surface of the electronic chip or distributed over a plurality of surfaces. In an example, the electronic chip is a flipped chip.

Electronic chip 102 is mounted on a first region 109 of a surface 111 of a substrate 107 of electronic device 100. Electronic chip 102 is coupled, for example via contact pads 110, to substrate 107 or to conductive tracks of substrate 107 and/or to components of substrate 107. The space between the first chip, its contact pads 110, and the substrate is, in an example, filled with a material conventionally used for the filling of spaces under electronic chips (“underfill”).

Substrate 107 comprises, for example, a ground layer 116 supporting a conductive surface, coupled to ground, and for example provided with an opening (not illustrated), for example in the form of a cross. The conductive surface coupled to ground is, for example, discontinuous. The ground layer comprises, for example, other signals, such as antenna signals, circulating on other conductive surfaces arranged in the same ground layer but insulated from the conductive surface coupled to ground.

Substrate 107 comprises, for example, a conductive signal layer 118 provided, for example, with at least one signal line (not illustrated) and arranged in front of at least a portion of the opening of ground layer 116. For example, at least a portion of the signal line(s) is aligned, or approximately aligned, vertically with respect to the opening of the ground layer. Ground layer 116 and signal layer 118 are, for example, offset with respect to each other according to the thickness of the substrate while being separated by an insulator which is, for example, a protection mask for the conductive layers. In an example, an insulator further separates the ground layer from a surface of the substrate. Electric contacts are coupled to the contact pads 110 of electronic chip 102. Substrate 107 comprises, for example, contact pads 120 on a surface of the substrate opposite to surface 111, for example in the form of balls. Contact pads 120 are, for example, used to couple and/or to bond substrate 107 to another substrate, not illustrated. These contact pads 120 are, for example, coupled to the ground layer or to the signal layer or to the contact pads 110 of electronic chip 102.

Signal layer 118 comprises, for example, one or a plurality of conductive surfaces coupled to ground and one or a plurality of conductive surfaces, insulated from ground, where signals, for example antenna signals, are present.

A first layer 105 of a first coating material covers, for example, at least one surface of the electronic chip 102 facing away from the substrate. This enables to protect the electronic chip against possible external elements such as humidity or electric shocks or also mechanical shocks.

First layer 105 is, for example, also arranged to cover a surface 126 of radiation element 106 facing away from substrate 107 and with a thickness 112 in the range, for example from 30 micrometers to 150 micrometers.

In an example, first coating layer 105 is deposited, for example, by compression or injection, and then cured by a thermal treatment. The first coating material is, for example, a matrix of epoxy resin with silica filling elements embedded inside.

Radiation element 106 is, for example, arranged at the level of a region 113 offset with respect to the region 109 of surface 111 of substrate 107 having electronic chip 102 mounted thereon so that the radiation element does not cover the electronic chip. This enables electronic device 100 to be relatively thin.

Radiation element 106 is, for example, separated from substrate 107 by a second layer 152 of a second dielectric material. The second dielectric material as well as its thickness will be selected by those skilled in the art according, for example, to its dielectric constant to optimize the performance of the antenna of the device. In an example, the second dielectric material is an epoxy resin with silica filling elements embedded inside and second layer 152 has a thickness 140 in the range from 260 to 290 micrometers. This enables to obtain an antenna optimized for frequencies in the order of 60 GHz. Thickness 140 is, for example, obtained and/or controlled to have an accuracy in the order of a few micrometers or of a few hundreds of micrometers. This enables to optimize the antenna performance.

In the example of FIG. 1, radiation element 106 rests on second layer 152 and has a lateral extension 108, counted horizontally, which is smaller than a lateral extension of second layer 152.

Lateral extension 108 is, for example, smaller than or equal to, or approximately equal to, 1 mm by 1 mm and the radiation element has, for example, a thickness in the order of one micrometer or smaller than a few tens of micrometers.

Radiation element 106 is covered, for example, by the first layer 105 of the first coating material, so that radiation element 106 is protected under the first coating material. The first coating material covers, for example, an upper surface 126 of radiation element 106 across a thickness 112 in the range, for example, from 30 to 150 micrometers. The thickness of layer 105 of the first coating material covering radiation element 106 will be selected, for example, to avoid too strongly disturbing the antenna radiation of radiation element 106 and to ensure a protection against external elements such as humidity or mechanical shocks.

An optional bonding element 150 is arranged, for example, between second layer 152 and substrate 107, on a surface opposite to radiation element 106 to bond at least second layer 152 to substrate 107. Bonding element 150 is, for example, a layer having a thickness in the range from 5 to 15 micrometers or also in the range from 10 micrometers to 50 micrometers. Bonding element 150 is, for example, a self-adhesive film formed, for example, with a resin having nonconductive filling elements (DAF, for “Die Attach Film”). Preferably, bonding element 150 has a thickness which has a tolerance in the order of 3 micrometers or in the order of a few micrometers. This enables to improve the antenna performance. Bonding element 150 has, for example, the same lateral extension as second layer 152 of the second material. When bonding element 150 is a self-adhesive film, its accuracy is controlled during its manufacturing. The accuracy is then better than, for example, glue deposited with a syringe.

In the example of FIG. 1, one or a plurality of alignment elements 146 are arranged at the level of substrate 107 to guide the positioning, for example, of second layer 152 and/or of bonding element 150. The positioning is performed, for example, with respect to a portion of ground layer 116. Alignment elements 146 are, for example, arranged in relief on surface 111 of substrate 107. In another example, not illustrated in FIG. 1, alignment elements 146 consist of openings in a surface layer of substrate 107.

Radiation element 106 interacts with the communication signal originating from electronic chip 102 to emit a radio frequency signal. Similarly, radiation element 106 may, for example, receive a radio frequency signal coming from the outside, towards electronic chip 102, such as, for example, a signal coming from an electronic device identical to that of FIG. 1.

In the example where a ground layer 116 is present in substrate 107, radiation element 106 interacts therewith so that, for example, an antenna signal is formed and transmitted towards the outside of the device.

In the example where a signal layer 118 is present, electronic chip 102 delivers, for example, a signal to be transmitted to the line or to the lines of the signal layer 118 and, for example, to a conductive surface of ground layer 116. Radiation element 106 interacts with a signal of the substrate. For example, the interaction occurs with a signal present in ground layer 116 and/or in signal layer 118 so that, for example, an antenna signal is formed and transmitted towards the outside of the device.

In another example, only radiation element 106 is present and substrate 107 comprises no ground line 116 and no signal line 118. In this case, radiation element 106 is coupled to a conductive line of substrate 107 which is in connection with electronic chip 102. A transmission signal is, for example, sent by electronic chip 102 to the conductive track of the substrate through contact pads 110, after which the signal is taken to radiation element 106, for example, over a via arranged between substrate 107 and radiation element 106. Such a via (not illustrated) is, for example, formed by laser direct structuring (LDS) or by a via provided, for example, with a conductive deposit to electrically couple a conductive layer of the substrate with radiation element 106 and arranged in first coating material 105.

Although, in the example of FIG. 1, electronic chip 102 is coupled to substrate 107 via contact pads 110, in other embodiments it will be possible for other connection types to be present as a variant or additionally, such as wire bondings.

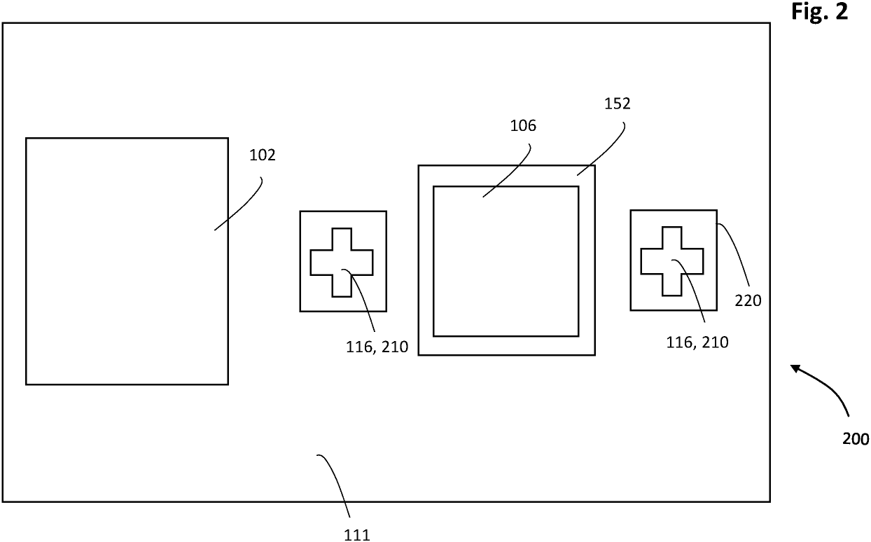

FIG. 2 is a top view showing an electronic device 200 according to another embodiment of the present disclosure.

The example of FIG. 2 is similar to that of FIG. 1 except for alignment elements 210, which replace the alignment elements 146 of FIG. 1 and which are arranged differently from those of FIG. 1. In the example of FIG. 2, alignment elements 210 are formed, for example, in a conductive surface of substrate 107, for example, a conductive surface of ground layer 116 which may be coupled to ground or insulated from ground. To be visible, an opening 220 is, for example, present through the insulator which is arranged between ground layer 116 and surface 111 of substrate 107, and further extends on either side of the pattern represented by each of alignment elements 210. In the example of FIG. 2, the pattern of alignment elements 210 is cross-shaped to allow a bidimensional alignment. Those skilled in the art may however select patterns adapted to needs.

In the example of FIG. 2, radiation element 106 has a rectangular shape in top view, and second layer 152 of the second material laterally extends on either side of radiation element 106.

In the example of FIG. 2, alignment elements 210 are located on each side of the assembly formed of radiation element 106 and of second layer 152 of the second material. This allows a more accurate alignment of radiation element 106 with respect to substrate 107 which, in return, enables to optimize the performance of the antenna.

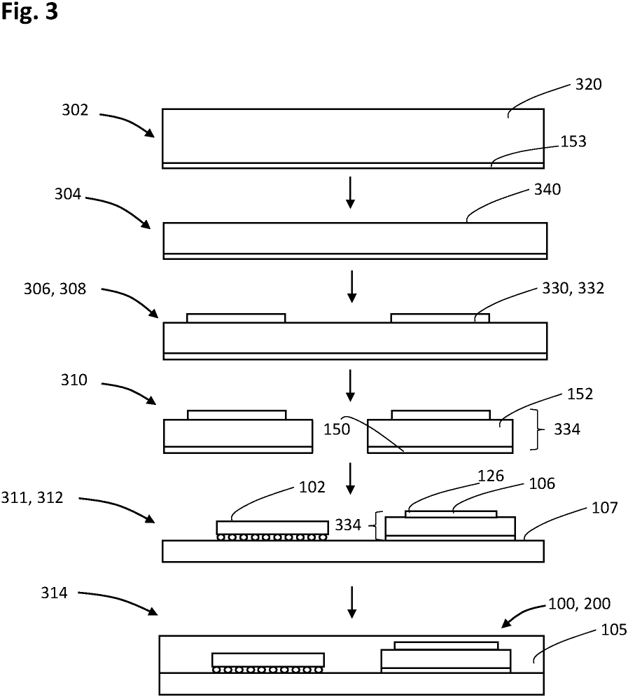

FIG. 3 shows a method of manufacturing the electronic device of FIG. 1 according to an embodiment of the present disclosure.

In a forming step 302, a layer 320 of the second dielectric material is formed to be intended to form the second layer 152 of the second material. In an example, the layer 320 of the second material is formed on a bonding portion 153 which is intended to form bonding element 150. The lateral extension of bonding portion 153 is, for example, greater than that of bonding element 150. In another example, not illustrated, at step 302, bonding portion 153 is not present.

At a step 304, the thickness 304 of layer 320 of the second dielectric material is decreased, for example by a grinding method, to reach the thickness 140 of second layer 152. In an example, not illustrated, at step 304, bonding portion 153 is not present.

At a step 306, a conductive layer 330, intended to form one or a plurality of radiation elements 106, is formed to rest on a surface 340 of layer 320 of the second material having had its thickness decreased at thickness decrease step 304. The lateral extension of layer 330 is greater than the lateral extension 108 of radiation element 106. In an example, not illustrated, at step 306, bonding portion 153 is not present.

At a step 308, conductive layer 330 is divided, for example by etching with a hard mask or a laser, into one or a plurality of conductive elements 332, each having lateral dimensions similar to those of radiation element 106.

At a step 310, the assembly obtained after steps 306, 308 is divided, for example by etching or mechanical cutting (also referred to in the art as singulation), into one or a plurality of blocks 334 of radiation elements. Each of blocks 334 then comprises, for example, at least one conductive element 332, a portion of layer 320 of the second material which forms second layer 152 of the second material and, optionally, bonding element 150. In another example, bonding portion 153 is placed into contact with layer 320 of the second material between step 308 and step 310.

In steps 311, 312, at least one block of radiation element 334 is positioned in contact with substrate 107 on which electronic chip 102 has been previously connected during step 311. The positioning of block 334 is performed so that radiation element 106 is offset with respect to the first region 109 of substrate 107 and does not cover electronic chip 102. In an example, not illustrated, the positioning comprises an alignment step where alignment elements 146 or 210 are used to position the block(s) 334 of radiation elements. After the picking, for example, automated, of the block 334 to be placed, the alignment is performed, for example, optically, with the help of one or a plurality of cameras tracking the alignment elements and retroacting on the elements to be placed (PICK AND PLACE). In an example where bonding element 150 is present under blocks 334, a thermal and/or compression treatment is for example applied to the blocks of radiation elements 334 after positioning. This enables to ensure a reliable and durable bonding. Although, in the example of FIG. 3, block 334 is positioned in contact with substrate 107 after electronic chip 102 has been mounted on substrate 107, in other examples, it would also be possible for electronic chip 102 to be mounted on substrate 107 after block 334 is positioned in contact with substrate 107.

At a step 314, first coating layer 105 is formed to cover, for example, at least a surface 126 of radiation element 106 and at least a surface of electronic chip 102 facing away from substrate 107.

In an optional step, not illustrated in FIG. 3, after step 314, the thickness of the coating material of the first layer is decreased so that the first layer 105 of coating material covers radiation element 106 with a thickness 112 in the range from 30 micrometers to 150 micrometers.

The preparation of the blocks 334 of radiation elements separately from substrate 107 enables, for example, to obtain accuracies in the order of a few micrometers for the thickness 140 of second layer 152 and/or on the positioning of radiation element 106. This further enables to be able to select the nature of the dielectric forming second layer 152.

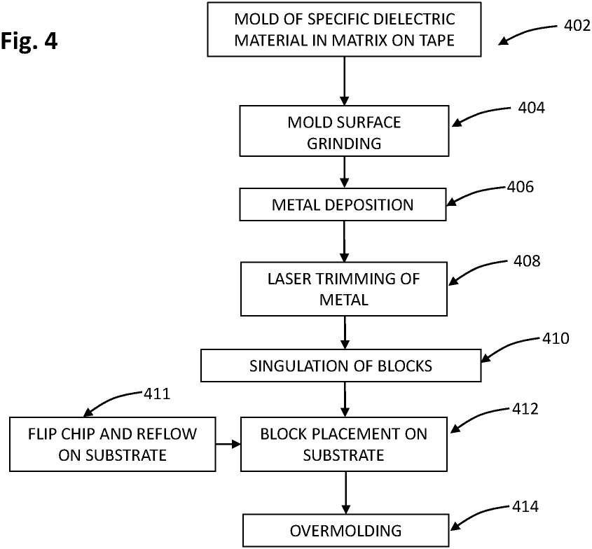

FIG. 4 shows the method of FIG. 3 in the form of blocks.

A step 402 (MOLD OF SPECIFIC DIELECTRIC MATERIAL IN MATRIX ON TAPE) corresponds to step 302 in the case where layer 320 is formed on bonding portion 153, which is for example in contact with a protection tape which is then removed.

A step 404 (MOLD SURFACE GRINDING) corresponds to step 304.

A step 406 (METAL DEPOSITION) corresponds to step 306. In this step, conductive layer 330 is, for example, deposited by plasma (Physical Vapor Deposition, PVD) or by evaporation or by chemical vapor deposition (CVD) or by wet deposition. A hard mask may be used during this step.

A step 408 (LASER TRIMMING OF METAL) corresponds to step 308 where the lateral extension of conductive layer 330 is decreased, for example, by laser etching, to delimit the radiation elements on surface 340.

A step 410 (SINGULATION OF BLOCKS) corresponds to step 310. In an example, not illustrated, bonding portion 153 is implemented in contact with layer 320 only between steps 408 and 410 and not at the level of step 402.

A step 411 (FLIP CHIP AND REFLOW ON SUBSTRATE) corresponds to the step of provision 311 of substrate 107 and of placing of electronic chip 102 into contact with substrate 107. In this step, a thermal treatment is, for example, applied to electronic chip 102 and to substrate 107 to ensure the partial melting, for example, of contact pads 110.

A step 412 (BLOCK PLACEMENT ON SUBSTRATE) corresponds to step 312.

A step 414 (OVERMOLDING) corresponds to step 314, first coating layer 105 being for example formed by overmolding.

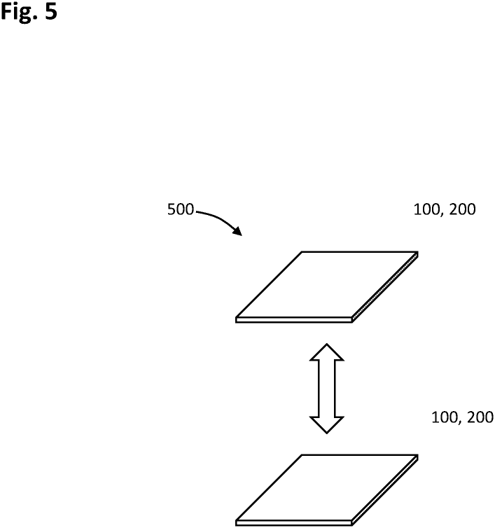

FIG. 5 shows an electronic system 500 according to an embodiment of the present disclosure. In the example of FIG. 5, electronic system 500 comprises two electronic devices 100, 200 similar to those of the examples of FIGS. 1 or 2, devices 100, 200 being arranged with respect to each other to be able either to receive or to transmit a signal to each other. The transmission or the reception of the signal is for example performed via their respective radiation element 106 or 206. In an example not illustrated, the number of electronic devices 100, 200 communicating together is, for example, greater than 2, for example three or some ten.

Various embodiments and variants have been described. Those skilled in the art will understand that certain features of these various embodiments and variants may be combined, and other variants will occur to those skilled in the art. For example, the distance between the radiation element and the substrate may be shorter than the thickness of the electronic chip. In another example, the radiation element has a lateral extension equal to that of the second layer or of the bonding element.

Finally, the practical implementation of the described embodiments and variations is within the abilities of those skilled in the art based on the functional indications given hereabove. In particular, as for the first coating material, which is selected among many materials adapted to being deposited, for example, by liquid deposition and then cured by heating or UV radiation or thermocompression and which provide, once cured, a protection against external elements such as humidity.

1. An electronic device, comprising:
a substrate;
an electronic integrated circuit chip mounted to a first region of the substrate;
a block comprising: a radiation element for an antenna mounted to a dielectric material layer;
wherein the block is mounted to a second region of the substrate that is offset with respect to the first region of the substrate;
a bonding element arranged between the block and the substrate, said bonding element attaching the dielectric material layer of the block to the substrate;
where the radiation element of the block does not cover the electronic integrated circuit chip; and
a coating layer of a coating material covering both the electronic integrated circuit chip mounted to the first region of the substrate and the block mounted to the second region of the substrate.

2. The electronic device according to claim 1, wherein the electronic integrated circuit chip is configured to excite the radiation element with a communication signal.

3. The electronic device according to claim 1, wherein the substrate comprises:
a ground layer supporting at least one conductive surface, coupled to ground, and provided with an opening; and
a signal layer provided with at least one signal line and arranged in front of at least a portion of the opening of the ground layer;
wherein the radiation element is arranged in front of at least a portion of the opening of the ground layer, the ground layer being arranged between the signal layer and the radiation element.

4. The electronic device according to claim 1, the bonding element has a thickness in a range from 5 to 15 micrometers.

5. The electronic device according to claim 1, wherein the dielectric material layer has a thickness in a range from 260 to 290 micrometers.

6. The electronic device according to claim 1, wherein the radiation element rests on the dielectric material layer and has a lateral extension which is smaller than a lateral extension of the dielectric material layer.

7. The electronic device according to claim 1, further comprising one or more alignment elements arranged at a level of the substrate and configured to guide positioning of the block for mounting to the substrate.

8. The electronic device according to claim 7, wherein said one or more alignment elements are located between the first and second regions of the substrate.

9. A method of manufacturing an electronic device, comprising:
forming a block comprising a radiation element for an antenna mounted to a dielectric material layer;
mounting an electronic integrated circuit chip at a first region of a substrate;
mounting the block at a second region of the substate that is offset with respect to the first region of the substrate;
wherein the element of the block does not cover the electronic integrated circuit chip;
forming a coating layer of a coating material covering both the electronic integrated circuit chip mounted to the first region of the substrate and the block mounted to the second region of the substrate.

10. The method according to claim 9, wherein the electronic integrated circuit chip is configured to excite the radiation element with a communication signal.

11. The method according to claim 9, further comprising forming the substrate to include:
a ground layer supporting at least one conductive surface, coupled to ground, and provided with an opening; and
a signal layer provided with at least one signal line and arranged in front of at least a portion of the opening of the ground layer.

12. The method according to claim 11, wherein mounting the block comprises attaching the block in front of at least a portion of the opening of the ground layer, the ground layer being arranged between the signal layer and the radiation element.

13. The method according to claim 9, further comprising using a bonding element positioned between the dielectric material layer of the block and the substrate to bond the block to the substrate.

14. The method according to claim 13, wherein the bonding element has a thickness in a range from 5 to 15 micrometers.

15. The method according to claim 9, wherein the dielectric material layer has a thickness in a range from 260 to 290 micrometers.

16. The method according to claim 90, wherein the radiation element rests on the dielectric material layer and has a lateral extension which is smaller than a lateral extension of the dielectric material layer.

17. The method according to claim 9, further comprising:
attaching one or more alignment elements to the substrate; and
wherein mounting the block comprises utilizes said one or more alignment elements to guide the positioning of block during mounting.

18. The method according to claim 9, wherein forming the block comprises:
forming a layer of dielectric material;
forming a conductive layer on a surface of said layer of dielectric material;
decreasing a thickness of said layer of dielectric material and the conductive layer so that said conductive layer is divided into one or more conductive elements, each having a lateral dimension similar to that of the radiation element; and
singulating to cut said block from an assembly obtained after forming.

19. The method according to claim 18, wherein, at an end of decreasing the thickness, a thickness of the second layer of the second material is in a range from 260 micrometers to 300 micrometers.

20. The method according to claim 9, further comprising performing a thermal or compression treatment that is applied to said block.

21. The method according to claim 9, wherein forming the coating layer comprises decreasing a thickness of coating material so that the coating material covers the radiation element with a thickness in a range from 30 micrometers to 150 micrometers.
